(19) United States
(12) Patent Application Publication
(10) Pub. No.: US 2023/0261022 A1
(43) Pub. Date: Aug. 17, 2023

(54) SOLID-STATE IMAGING DEVICE

(71) Applicant: SONY SEMICONDUCTOR SOLUTIONS CORPORATION, Kanagawa (JP)

(72) Inventors: Kunihiro KOMORI, Kumamoto (JP); Yasuyuki SHIGA, Kumamoto (JP); Shingo YAMAGUCHI, Kumamoto (JP)

(73) Assignee: SONY SEMICONDUCTOR SOLUTIONS CORPORATION, Kanagawa (JP)

(21) Appl. No.: 18/004,784

(22) PCT Filed: Jul. 8, 2021
(86) PCT No.: PCT/JP2021/025748

§ 371 Date: Jan. 9, 2023

(30) Foreign Application Priority Data
Jul. 20, 2020 (JP) 2020-124051

(51) Int. Cl. H01L 27/146

(52) U.S. Cl. CPC H01L 27/1463; H01L 27/14649; H01L 27/14683; G01S 17/894

(57) ABSTRACT

A solid-state imaging device as disclosed includes a plurality of photoelectric conversion units, a pair of voltage application units, a charge detection unit, and a pixel separation unit. The photoelectric conversion units are in a semiconductor layer The pair of voltage application units are on the opposite side of the semiconductor layer from a light incident surface side. The charge detection unit annularly surrounds each of the voltage application units in plan view and detects the signal charges distributed according to alternate application of a predetermined voltage to the pair of voltage application units. The pixel separation unit partitions and separates the semiconductor layer for each of the photoelectric conversion units in plan view and extends in a depth direction of the semiconductor layer from the light incident surface. An insulating film having a film thickness of 2 nm or more is provided between the pixel separation unit and the semiconductor layer.

### FIELD

The present disclosure relates to a solid-state imaging device.

### BACKGROUND

A ranging system using an indirect time of flight (ToF) method irradiates an object with irradiation light such as infrared light and receives and detects, by a solid-state imaging device, reflected light obtained by reflecting the irradiation light at the surface of the object. The ranging system detects the time from irradiation of irradiation light to reception of reflected light as a phase difference and calculates the distance to the object based on the phase difference.

The solid-state imaging device includes a pixel array in which a plurality of light receiving pixels are arranged in a matrix in plan view. Each light receiving pixel includes a photoelectric conversion unit that photoelectrically converts incident light into signal charges, and a charge storage unit that temporarily holds the photoelectrically converted signal charges.

As such a solid-state imaging device, there is a solid-state imaging device in which two charge storage units are provided for each photoelectric conversion unit, and signal charges obtained by photoelectric conversion are divided into the two charge storage units. For example, Patent Literature 1 discloses a solid-state imaging device including a pair of voltage application units provided for each photoelectric conversion unit, and a charge detection unit that annularly surrounds each of the voltage application units and detects signal charges distributed according to alternate application of a predetermined voltage to the pair of voltage application units.

### CITATION LIST

### Patent Literature

Patent Literature 1: JP 2018-117117 A

SUMMARY

Technical Problem

However, in the above-described conventional technology, it is difficult to inhibit both deterioration of image quality due to light leaking to adjacent photoelectric conversion units and deterioration of charge transfer efficiency from the photoelectric conversion units to the charge detection unit.

The present disclosure proposes a solid-state imaging device capable of inhibiting both deterioration of image quality due to light leaking to adjacent photoelectric conversion units and deterioration of charge transfer efficiency from the photoelectric conversion units to the charge detection unit. Solution to Problem

According to the present disclosure, a solid-state imaging device is provided. The solid-state imaging device includes a plurality of photoelectric conversion units, a pair of voltage application units, a charge detection unit, a pixel separation unit, and an insulating film having a film thickness of 2 nm or more. The photoelectric conversion units are provided in a matrix in a semiconductor layer in plan view and photoelectrically convert incident light into signal charges. The pair of voltage application units are provided on the opposite side of the semiconductor layer from a light incident surface of the semiconductor layer. The charge detection unit annularly surrounds each of the voltage application units in plan view and detects the signal charges distributed according to alternate application of a predetermined voltage to the pair of voltage application units. The pixel separation unit partitions and separates the semiconductor layer for each of the photoelectric conversion units in plan view and extends in a depth direction of the semiconductor layer from the light incident surface. The insulating film having a film thickness of 2 nm or more is provided between the pixel separation unit and the semiconductor layer.

### BRIEF DESCRIPTION OF DRAWINGS

FIG. 1 is a diagram illustrating a configuration example of a solid-state imaging device according to the present disclosure.

FIG. 2 is an explanatory diagram of a sectional structure of a pixel array unit according to the present disclosure.

FIG. 3 is a diagram illustrating an interface part between a typical pixel separation unit and silicon.

FIG. 4 is a diagram illustrating an interface part between a pixel separation unit and silicon according to the present disclosure.

FIG. 5 is a diagram illustrating movements of signal charges in a semiconductor layer according to the present disclosure.

FIG. 6 is a diagram illustrating a production step of a pixel array according to the present disclosure.

FIG. 7 is a diagram illustrating a production step of the pixel array according to the present disclosure.

FIG. 8 is a diagram illustrating a production step of the pixel array according to the present disclosure.

FIG. 9 is a diagram illustrating a production step of the pixel array according to the present disclosure.

### DESCRIPTION OF EMBODIMENTS

Hereinafter, embodiments of the present disclosure will be described in detail with reference to the drawings. In each of the following embodiments, the same portions are denoted by the same reference signs, and repetitive description are omitted.

### 1. Configuration Example of Solid-State Imaging Device

The present technology may be applied to, for example, a solid-state imaging device included in a ranging system that performs ranging by an indirect time of flight (ToF) method, an imaging device including such a solid-state imaging device, and the like.

For example, the ranging system may be applied to an in-vehicle system that is mounted on a vehicle and measures a distance to an object outside the vehicle, a gesture recognition system that measures a distance to an object such as a hand of a user and recognizes a gesture of the user based on a measurement result, and the like. In this case, the result of the gesture recognition may be used for, for example, an operation of a car navigation system.

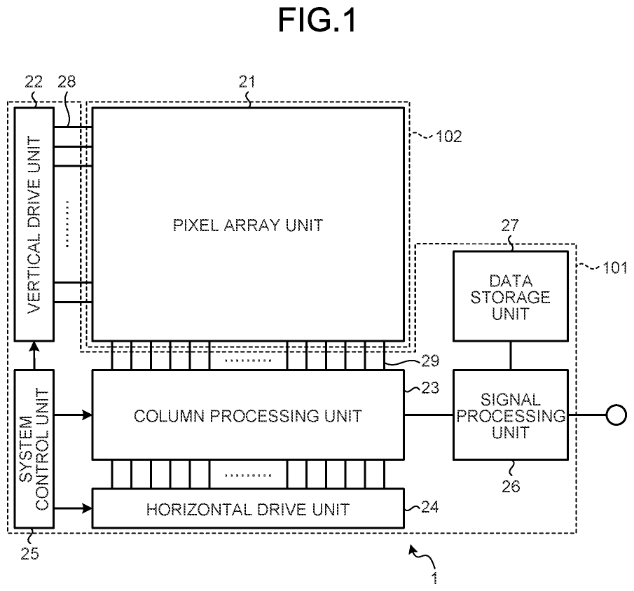

FIG. 1 is a diagram illustrating a configuration example of a solid-state imaging device according to the present disclosure. A solid-state imaging device 1 illustrated in FIG. 1 is a back-illuminated current assisted photonic demodulator (CAPD) sensor and is provided in an imaging device having a ranging function.

The solid-state imaging device 1 includes a circuit board 101 and a sensor board 102 stacked on the circuit board 101. The sensor board 102 is provided with a pixel array unit 21 in which a plurality of light receiving pixels (hereinafter, simply referred to as “pixels”) are arranged in a matrix in plan view.

The circuit board 101 is provided with a peripheral circuit. The peripheral circuit includes, for example, a vertical drive unit 22, a column processing unit 23, a horizontal drive unit 24, and a system control unit 25. The vertical drive unit 22 includes, for example, a pixel transistor that processes signal charges photoelectrically converted in each pixel. Here, the components are illustrated on the same plane to facilitate understanding of a connection relationship between the components of the circuit board 101 and the components of the sensor board 102.

The solid-state imaging device 1, in which the pixels of the pixel array unit 21 are provided on the sensor board 102, and the pixel transistor is provided on the circuit board 101 as described above, can improve the charge collection efficiency and reduce the power consumption.

The circuit board 101 is further provided with a signal processing unit 26 and a data storage unit 27. The signal processing unit 26 and the data storage unit 27 may be mounted on the same board as the circuit board 101 or may be disposed on a board different from the circuit board 101.

The pixel array unit 21 has a configuration in which pixels that generate signal charges according to the amount of received light and output signals according to the signal charges are two-dimensionally arranged in a row direction and a column direction, that is, arranged in a matrix. That is, the pixel array unit 21 includes a plurality of photoelectric conversion units that photoelectrically convert incident light for each pixel and output a signal corresponding to signal charges obtained as a result.

The row direction refers to an arrangement direction of pixels in a pixel row (that is, in a horizontal direction), and the column direction refers to an arrangement direction of pixels in a pixel column (that is, in a vertical direction). That is, the row direction is a lateral direction in the drawing, and the column direction is a longitudinal direction in the drawing.

In the pixel array unit 21, a pixel drive line 28 is wired along the row direction for each pixel row and two vertical signal lines 29 are wired along the column direction for each pixel column with respect to the pixel array in the matrix form. For example, the pixel drive line 28 transmits a drive signal for performing driving when a signal is read out from a pixel. In FIG. 1, the pixel drive line 28 is illustrated as one wiring, but it is not limited to one wiring. One end of the pixel drive line 28 is connected to an output end corresponding to each row of the vertical drive unit 22.

The vertical drive unit 22 includes a shift register and an address decoder, and it drives all the pixels of the pixel array unit 21 at the same time or in units of rows. That is, the vertical drive unit 22 constitutes a drive unit that controls the operation of each pixel of the pixel array unit 21 together with the system control unit 25 that controls the vertical drive unit 22.

A signal output from each pixel of the pixel row according to the drive control by the vertical drive unit 22 is input to the column processing unit 23 through the vertical signal line 29. The column processing unit 23 performs predetermined signal processing on the signal output from each pixel through the vertical signal line 29 and temporarily holds pixel signals after the signal processing.

Specifically, the column processing unit 23 performs noise removal processing, analog to digital (AD) conversion processing, and the like as signal processing.

The horizontal drive unit 24 includes a shift register and an address decoder, and it sequentially selects unit circuits corresponding to pixel columns of the column processing unit 23. Through the selective scanning by the horizontal drive unit 24, the pixel signals subjected to signal processing for each unit circuit in the column processing unit 23 are sequentially output.

The system control unit 25 includes a timing generator that generates various timing signals, and it performs drive control of the vertical drive unit 22, the column processing unit 23, the horizontal drive unit 24, and the like based on the various timing signals generated by the timing generator.

The signal processing unit 26 has at least an arithmetic processing function and performs various signal processing such as arithmetic processing based on the pixel signals output from the column processing unit 23. The data storage unit 27 temporarily stores data necessary for signal processing in the signal processing unit 26.

### 2. Sectional Structure of Pixel Array Unit

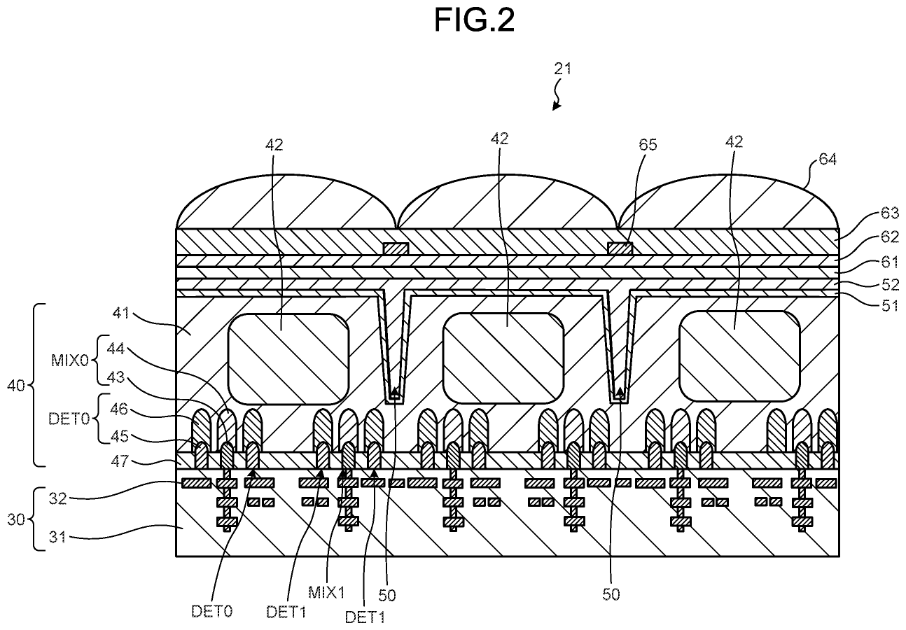

Next, a sectional structure of the pixel array unit 21 will be described with reference to FIG. 2. FIG. 2 is an explanatory diagram of a sectional structure of the pixel array unit 21 according to the present disclosure. FIG. 2 selectively illustrates a cross section of three pixels in the pixel array unit 21.

As illustrated in FIG. 2, the pixel array unit 21 includes a multilayer wiring layer 30, a semiconductor layer 40 stacked on the multilayer wiring layer 30, and an insulating film 51, an antireflection film 52, interlayer insulating films 61, 62, a planarization film 63, and a microlens 64 sequentially stacked on the semiconductor layer 40.

The multilayer wiring layer 30 includes, for example, an interlayer insulating film 31 formed of silicon oxide and a multilayer wiring 32 such as a copper wiring provided inside the interlayer insulating film 31. The semiconductor layer 40 includes, for example, a P-type silicon substrate 41 doped with impurities such as boron, a plurality of photoelectric conversion units 42 provided inside the silicon substrate 41, voltage application units MIX0, MIX1, and charge detection units DET0, DET1.

The photoelectric conversion unit 42 is a region formed by, for example, ion-implanting N-type impurities such as phosphorus into the silicon substrate 41. The photoelectric conversion unit 42 is provided in a matrix in the semiconductor layer 40 in plan view, and it photoelectrically converts light condensed and incident by the microlens 64 into signal charges.

The voltage application units MIX0, MIX1 are provided on the opposite side of the semiconductor layer 40 from a light incident surface of the semiconductor layer 40. The pair of voltage application units MIX0, MIX1 are provided for each photoelectric conversion unit 42. The voltage application units MIX0, MIX1 include a P+ region 43 in which a relatively high-concentration P-type impurity is ion-implanted into the silicon substrate 41, and a P− region 44 in which a relatively low-concentration P-type impurity is ion-implanted to cover the P+ region 43.

The charge detection unit DET0 is provided to annularly surround the voltage application unit MIX0 in plan view. The charge detection unit DET1 is provided to annularly surround the voltage application unit MIX1 in plan view.

The charge detection units DET0, DET1 include an N+ region 45 in which a relatively high-concentration N-type impurity is ion-implanted into the silicon substrate 41, and an N− region 46 in which a relatively low-concentration N-type impurity is ion-implanted to cover the N+ region 45. Each P+ region 43 and each N+ region 45 are insulated by a silicon oxide film 47.

The pixel array unit 21 includes a pixel separation unit 50 that partitions and separates the semiconductor layer 40 for each photoelectric conversion unit 42 in plan view and extends in a depth direction of the semiconductor layer 40 from the light incident surface. The pixel separation unit 50 is formed of an antireflection material and is continuous with the antireflection film 52 stacked on the semiconductor layer 40. In the planarization film 63, a light shielding member 65 is provided at a position overlapping the pixel separation unit 50 in plan view.

The pixel array unit 21 having the configuration as illustrated in FIG. 2 is called a current assisted photonic demodulator (CAPD). The CAPD type pixel array unit 21 includes three charge storage units (floating diffusions) for each photoelectric conversion unit 42 and distributes photoelectrically converted signal charges to two floating diffusions by switching the direction of a current flowing in each photoelectric conversion unit 42.

The operation of the CAPD type pixel array unit 21 will be described. The pixel array unit 21 photoelectrically converts incident light condensed by the microlens 64 into electrons to be signal charges through the photoelectric conversion unit 42.

Thereafter, the pixel array unit 21 applies a positive voltage (for example, 1.5 V) to the voltage application unit MIX1 and applies 0 V or a negative voltage to the voltage application unit MIX0 at a certain timing. This causes a current to flow from the voltage application unit MIX1 to the voltage application unit MIX0 inside the photoelectric conversion unit 42. The electrons of the signal charges are induced to the charge detection unit DET1 by an electric field generated by the current and are taken in and detected by the charge detection unit DET1.

The charge detection unit DET1 is connected to a first floating diffusion by the multilayer wiring 32 and transfers the detected signal charges to the first floating diffusion. The signal charges are temporarily held in the first floating diffusion and then read out to the column processing unit 23 (see FIG. 1).

At the next timing, the pixel array unit 21 applies a positive voltage (for example, 1.5 V) to the voltage application unit MIX0 and applies 0 V or a negative voltage to the voltage application unit MIX1. This causes a current to flow from the voltage application unit MIX0 to the voltage application unit MIX1 inside the photoelectric conversion unit 42. The electrons of the signal charges are induced to the charge detection unit DET0 by an electric field generated by the current and are taken in and detected by the charge detection unit DET0.

The charge detection unit DET0 is connected to a second floating diffusion by the multilayer wiring 32 and transfers the detected signal charges to the second floating diffusion. The signal charges are temporarily held in the second floating diffusion and then read out to the column processing unit 23 (see FIG. 1).

In a typical CAPD type pixel array, light incident on a photoelectric conversion unit may be reflected in a semiconductor layer and may enter adjacent surrounding photoelectric conversion units as leaking light to cause color mixing. When color mixing occurs, an edge portion of a subject is blurred in a captured image, and the image quality deteriorates.

In contrast, the pixel array unit 21 according to the present disclosure includes the pixel separation unit 50 that partitions and separates the semiconductor layer 40 for each photoelectric conversion unit 42 in plan view and extends in the depth direction of the semiconductor layer 40 from the light incident surface. The pixel separation unit 50 is formed of, for example, a metal oxide having an antireflection function, such as aluminum oxide.

As a result, in the pixel array unit 21, even when light incident on the photoelectric conversion unit 42 is reflected in the semiconductor layer 40, the pixel separation unit 50 prevents light from entering adjacent photoelectric conversion units 42, so that the occurrence of color mixing can be inhibited.

However, if the pixel array unit 21 is simply provided with the pixel separation unit 50 having a trench shape, the electron transfer efficiency from the photoelectric conversion unit 42 to the charge detection units DET0, DET1 decreases. Thus, the pixel array unit 21 includes the insulating film 51 having a film thickness of 2 nm or more between the pixel separation unit 50 and the silicon of the semiconductor layer 40 to inhibit a decrease in electron transfer efficiency. The insulating film 51 is, for example, a silicon oxide film. The insulating film 51 may be a silicon nitride film.

### 3. Operation and Effect of Insulating Film

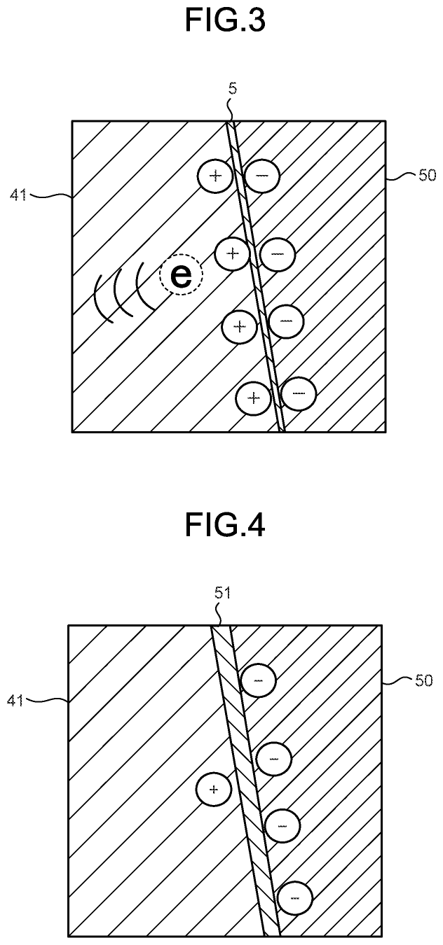

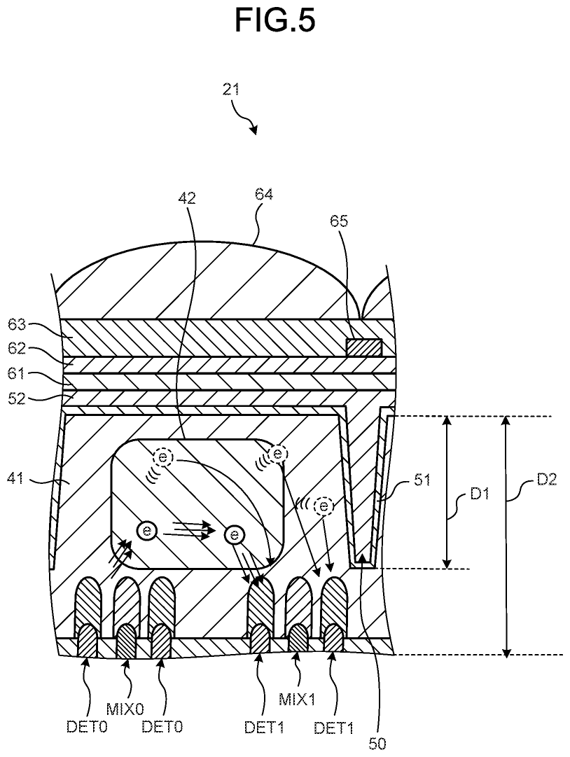

Next, with reference to FIGS. 3 to 5, the operation and effect by providing the insulating film 51 having a film thickness of 2 nm or more will be described. FIG. 3 is a diagram illustrating an interface part between a typical pixel separation unit and silicon. FIG. 4 is a diagram illustrating an interface part between the pixel separation unit and silicon according to the present disclosure. FIG. 5 is a diagram illustrating movements of signal charges in the semiconductor layer according to the present disclosure.

The typical pixel separation unit is formed by forming a trench at a position where the pixel separation unit is to be formed in the silicon substrate 41, cleaning the silicon substrate 41, and then embedding a metal oxide having an antireflection function, such as aluminum oxide, in the trench.

At this time, as illustrated in FIG. 3, a natural oxide film 5, having a very thin film thickness of 1 nm, excites holes (positive holes) in an interface part with the silicon substrate 41 by the influence of the negatively charged pixel separation unit 50 to generate a hole current.

As a result, part of the photoelectrically converted signal charges (electrons) to be originally taken into the charge detection units DET0, DET1 is attracted by the hole current and is not transferred to the charge detection units DET0, DET1. Thus, with the typical pixel separation unit 50 illustrated in FIG. 3, color mixing can be inhibited, but the electron transfer efficiency decreases.

As illustrated in FIG. 4, the pixel array unit 21 according to the present disclosure includes the insulating film 51 having a film thickness of 2 nm or more, which is larger than the film thickness of the natural oxide film 5, between the pixel separation unit 50 and the silicon substrate 41 in the semiconductor layer 40.

This causes the pixel array unit 21 to have an increased distance between the negatively charged pixel separation unit 50 and the silicon substrate 41, resulting in a reduction in holes (positive holes) excited at the interface part of the insulating film 51 with the silicon substrate 41.

Thus, according to the pixel array unit 21, it is possible to transfer, to the charge detection unit DET1, signal charges that are photoelectrically converted in the vicinity of the pixel separation unit 50 and the antireflection film 52 and are difficult to transfer to the charge detection unit DET1 without the insulating film 51, like the electrons indicated by dotted lines in FIG. 5. As a result, the pixel array unit 21 can inhibit a decrease in electron transfer efficiency.

In addition, the depth of the pixel separation unit 50 in the pixel array unit 21 is limited because if the depth of the pixel separation unit 50 is too deep, the distances between the pixel separation unit 50 and the charge detection units DET0, DET1 become short, the signal charges are attracted to the pixel separation unit 50, and the charge transfer efficiency decreases.

Specifically, in the pixel array unit 21, a depth D1 of the pixel separation unit 50 from the light incident surface of the semiconductor layer 40 is limited to 0.67 times or less a thickness D2 of the semiconductor layer 40. Thus, for example when the thickness of the semiconductor layer 40 is 6.7 μm, the depth of the pixel separation unit 50 is 4.5 μm or less.

This enables the pixel array unit 21 to inhibit a decrease in electron transfer efficiency by securing the distances between the pixel separation unit 50 and the charge detection units DET0, DET1 to such an extent that transfer of signal charges is not affected.

### 4. Method for Producing Pixel Array

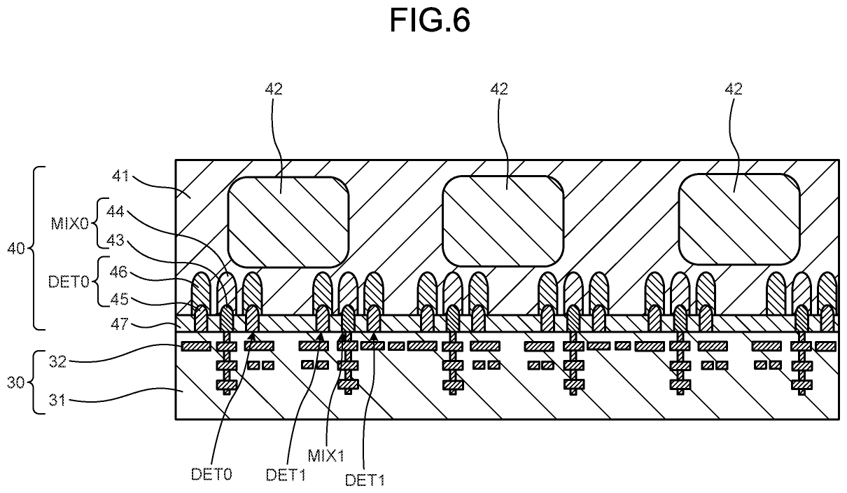

Next, a method for producing the pixel array unit 21 will be described with reference to FIGS. 6 to 9. FIGS. 6 to 9 are diagrams illustrating production steps of the pixel array according to the present disclosure.

As illustrated in FIG. 6, first, an N-type impurity is ion-implanted into predetermined positions inside the P-type silicon substrate 41 from the front surface (lower surface), and an annealing treatment is performed to form the photoelectric conversion unit 42 and the charge detection units DET0, DET1 inside the silicon substrate 41.

Further, a P-type impurity is ion-implanted into predetermined positions inside the silicon substrate 41 from the front surface (lower surface), and an annealing treatment is performed to form the voltage application units MIX0, MIX1 inside the silicon substrate 41. Thereafter, the silicon oxide film 47 is formed between the charge detection units DET0, DET1 and the voltage application units MIX0, MIX1 to insulate them.

Subsequently, the interlayer insulating film 31 and a wiring pattern are sequentially stacked on the front surface (lower surface) of the silicon substrate 41 to form the multilayer wiring layer 30. Then, the silicon substrate 41 is ground and polished from the back surface side to be thinned.

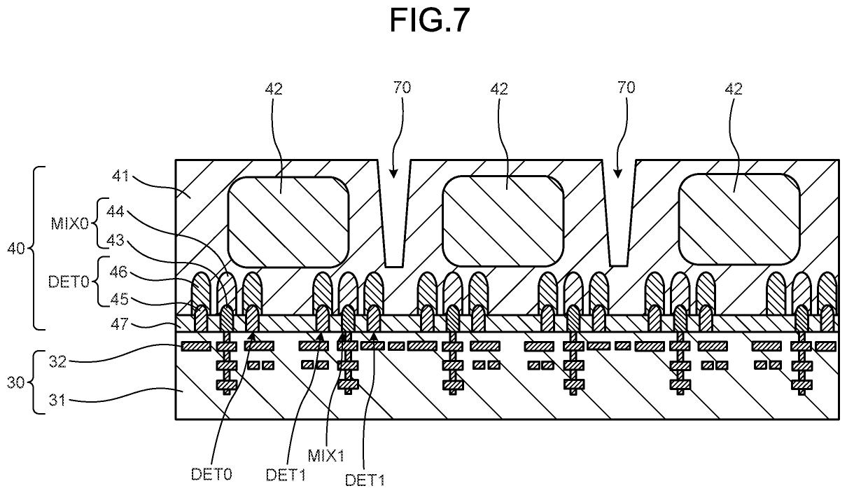

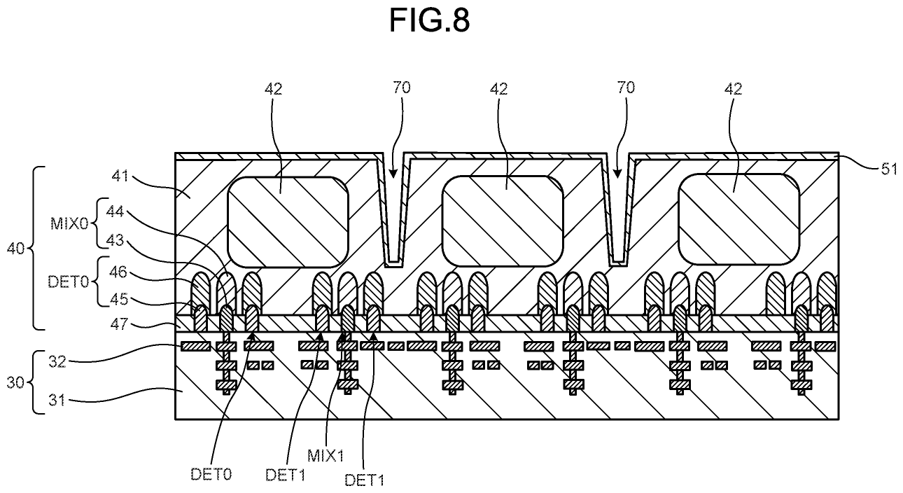

Thereafter, as illustrated in FIG. 7, a trench 70 is formed from the back surface side at a position where the pixel separation unit 50 (see FIG. 2) is to be formed in the silicon substrate 41, and the silicon substrate 41 is cleaned. Subsequently, as illustrated in FIG. 8, for example, a silicon oxide film is formed on the back surface (upper surface) of the silicon substrate 41 and the inner peripheral surface of the trench 70 so that the film has a film thickness of 2 nm or more, whereby the insulating film 51 is formed.

In this manner, the insulating film 51 can extend from between the pixel separation unit 50 and the silicon substrate 41 to the light incident surface of the silicon substrate 41. As a result, signal charges photoelectrically converted in the vicinity of the back surface (upper surface) of the silicon substrate 41 can also be efficiently transferred to the charge detection units DET0, DET1.

The insulating film 51 is formed by, for example, atomic layer deposition (ALD). With this method, the film thickness of the insulating film 51 can be accurately controlled at an atomic layer level. The method for forming the insulating film 51 is not limited to ALD.

The insulating film 51 may also be formed by, for example, thermal oxidation, chemical vapor deposition (CVD), plasma oxidation, in-situ-steam generation (ISSG), or the like.

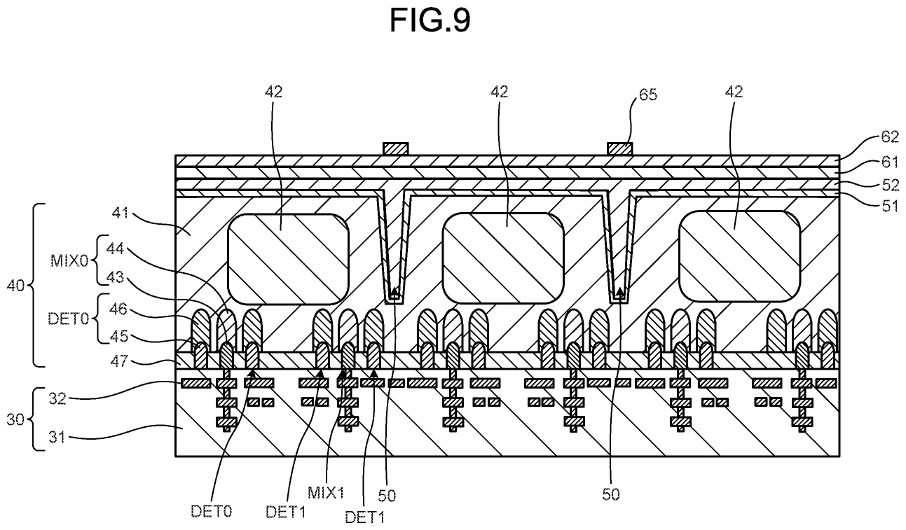

Thereafter, as illustrated in FIG. 9, for example, aluminum oxide is deposited on the back surface of the silicon substrate 41 and inside the trench 70 to form the antireflection film 52 and the pixel separation unit 50. The pixel separation unit 50 may also be formed of a material containing at least one element of hafnium, zirconium, aluminum, tantalum, titanium, yttrium, and lanthanoid elements. The pixel separation unit 50 containing these elements can also prevent light from being reflected inside the semiconductor layer 40.

Subsequently, the interlayer insulating films 61, 62 are sequentially stacked on the antireflection film 52. The interlayer insulating films 61, 62 are formed of, for example, silicon oxide or silicon nitride. Then, the light shielding member 65 is formed at a position overlapping the pixel separation unit 50 in plan view on the interlayer insulating film 62.

Thereafter, the planarization film 63 made of resin is formed on the interlayer insulating film 62 and the light shielding member 65, and the microlens 64 is stacked on the planarization film 63, whereby the pixel array unit 21 illustrated in FIG. 2 is completed. A silicon oxide film is used as the insulating film 51 here, but the insulating film 51 may be a silicon nitride film.

The silicon nitride film, due to its low ion conductivity, can prevent movement of oxygen ions O²⁻ from a natural oxide film to the pixel separation unit 50 and the antireflection film 52 even with the natural oxide film formed on the back surface (upper surface) of the silicon substrate 41 and the inner peripheral surface of the trench 70 by the cleaning step. The insulating film 51 can be formed at a lower cost by using a silicon oxide film than using silicon nitride as the insulating film 51.

The insulating film 51 may be a metal oxide film having a positive fixed charge. The metal oxide film having a positive fixed charge contains, for example, at least wither yttrium oxide or lanthanum oxide. Such an insulating film 51 can also inhibit excitation of holes (positive holes) at an interface part of the silicon substrate 41 with the insulating film 51.

### 5. Effects

The solid-state imaging device 1 includes a plurality of photoelectric conversion units 42, a pair of voltage application units MIX0, MIX1, charge detection units DET0, DET1, a pixel separation unit 50, and an insulating film 51 having a film thickness of 2 nm or more. The plurality of photoelectric conversion units 42 are provided in a matrix in the semiconductor layer 40 in plan view and photoelectrically converts incident light into signal charges. The pair of voltage application units MIX0, MIX1 are provided on the opposite side of the semiconductor layer 40 from the light incident surface of the semiconductor layer 40. The charge detection units DET0, DET1 annularly surround the voltage application units MIX0, MIX1 in plan view and detect signal charges distributed according to alternate application of a predetermined voltage to the pair of voltage application units MIX0, MIX1. The pixel separation unit 50 partitions and separates the semiconductor layer 40 for each photoelectric conversion unit 42 in plan view and extends in the depth direction of the semiconductor layer 40 from the light incident surface. The insulating film having a film thickness of 2 nm or more is provided between the pixel separation unit 50 and the semiconductor layer 40. This causes the solid-state imaging device 1 to have an increased distance between the pixel separation unit 50 and the silicon substrate 41 in the semiconductor layer 40, which can inhibit both deterioration of image quality due to light leaking to adjacent photoelectric conversion units 42 and deterioration of charge transfer efficiency from the photoelectric conversion unit 42 to the charge detection units DET0, DET1.

The depth of the pixel separation unit 50 from the light incident surface of the semiconductor layer 40 is 0.67 times or less the thickness of the semiconductor layer 40. This enables the solid-state imaging device 1 to inhibit a decrease in electron transfer efficiency by securing the distances between the pixel separation unit 50 and the charge detection units DET0, DET1 to such an extent that transfer of signal charges is not affected.

The insulating film 51 extends onto the light incident surface of the semiconductor layer 40. This enables the solid-state imaging device 1 to efficiently transfer the signal charges photoelectrically converted in the vicinity of the back surface (upper surface) serving as the light incident surface of the silicon substrate 41 to the charge detection units DET0, DET1.

The insulating film 51 is a silicon oxide film. Because of this, the insulating film 51 can be formed at a lower cost than a silicon nitride film.

Alternatively, the insulating film 51 is a silicon nitride film. The silicon nitride film, due to its low ion conductivity, can prevent movement of oxygen ions O⁻ from a natural oxide film to the pixel separation unit 50 and the antireflection film 52 even with the natural oxide film formed on the back surface (upper surface) of the silicon substrate 41 and the inner peripheral surface of the trench 70 by the cleaning step.

Alternatively, the insulating film 51 is a metal oxide film having a positive fixed charge. This enables the solid-state imaging device 1 to inhibit excitation of holes (positive holes) at the interface part of the silicon substrate 41 with the insulating film 51.

The metal oxide film contains at least either yttrium oxide or lanthanum oxide. This enables the solid-state imaging device 1 to inhibit excitation of holes (positive holes) at the interface part of the silicon substrate 41 with the insulating film 51.

The insulating film 51 is formed by atomic layer deposition (ALD). With this method, the film thickness of the insulating film 51 can be accurately controlled at an atomic layer level.

The pixel separation unit 50 contains at least one element of hafnium, zirconium, aluminum, tantalum, titanium, yttrium, and lanthanoid elements. This enables the pixel separation unit 50 to prevent light from being reflected inside the semiconductor layer 40.

The effects described in the present specification are merely examples and are not restrictive of the disclosure herein, and other effects may be achieved.

The present technology can also have the following configurations.

(1)

A solid-state imaging device including:

a plurality of photoelectric conversion units provided in a matrix in a semiconductor layer in plan view and photoelectrically converting incident light into signal charges;

a pair of voltage application units provided on an opposite side of the semiconductor layer from a light incident surface of the semiconductor layer;

a charge detection unit that annularly surrounds each of the voltage application units in plan view and detects the signal charges distributed according to alternate application of a predetermined voltage to the pair of voltage application units;

a pixel separation unit that partitions and separates the semiconductor layer for each of the photoelectric conversion units in plan view, the pixel separation unit extending in a depth direction of the semiconductor layer from the light incident surface; and

an insulating film provided between the pixel separation unit and the semiconductor layer, the insulating film having a film thickness of 2 nm or more.

(2)

The solid-state imaging device according to (1), wherein

the pixel separation unit has

a depth from the light incident surface of the semiconductor layer of 0.67 times or less a

thickness of the semiconductor layer.

(3)

The solid-state imaging device according to (1) or (2), wherein

the insulating film extends onto the light incident surface of the semiconductor layer.

(4)

The solid-state imaging device according to any one of (1) to (3), wherein

the insulating film is

a silicon oxide film.

(5)

The solid-state imaging device according to any one of (1) to (3), wherein

the insulating film is

a silicon nitride film.

(6)

The solid-state imaging device according to any one of (1) to (3), wherein

the insulating film is

a metal oxide film having a positive fixed charge.

(7)

The solid-state imaging device according to (6), wherein

the metal oxide film contains

at least either yttrium oxide or lanthanum oxide.

(8)

The solid-state imaging device according to any one of (1) to (7), wherein

the insulating film is

formed by atomic layer deposition (ALD).

(9)

The solid-state imaging device according to any one of (1) to (8), wherein

the pixel separation unit contains

at least one element of hafnium, zirconium, aluminum, tantalum, titanium, yttrium, and lanthanoid elements.

### REFERENCE SIGNS LIST

1 SOLID-STATE IMAGING DEVICE

21 PIXEL ARRAY UNIT

22 VERTICAL DRIVE UNIT

23 COLUMN PROCESSING UNIT

24 HORIZONTAL DRIVE UNIT

25 SYSTEM CONTROL UNIT

26 SIGNAL PROCESSING UNIT

27 DATA STORAGE UNIT

30 MULTILAYER WIRING LAYER

31, 61, 62 INTERLAYER INSULATING FILM

32 MULTILAYER WIRING

40 SEMICONDUCTOR LAYER

41 SILICON SUBSTRATE

42 PHOTOELECTRIC CONVERSION UNIT

MIX0, MIX1 VOLTAGE APPLICATION UNIT

DET0, DET1 CHARGE DETECTION UNIT

50 PIXEL SEPARATION UNIT

51 INSULATING FILM

52 ANTIREFLECTION FILM

63 PLANARIZATION FILM

64 MICROLENS

65 LIGHT SHIELDING MEMBER

What is claimed is:

1. A solid-state imaging device, comprising:
a plurality of photoelectric conversion units provided in a matrix in a semiconductor layer in plan view and photoelectrically converting incident light into signal charges;
a pair of voltage application units provided on an opposite side of the semiconductor layer from a light incident surface of the semiconductor layer;
a charge detection unit that annularly surrounds each of the voltage application units in plan view and detects the signal charges distributed according to alternate application of a predetermined voltage to the pair of voltage application units;
a pixel separation unit that partitions and separates the semiconductor layer for each of the photoelectric conversion units in plan view, the pixel separation unit extending in a depth direction of the semiconductor layer from the light incident surface; and
an insulating film provided between the pixel separation unit and the semiconductor layer, the insulating film having a film thickness of 2 nm or more.

2. The solid-state imaging device according to claim 1, wherein
the pixel separation unit has
a depth from the light incident surface of the semiconductor layer of 0.67 times or less a thickness of the semiconductor layer.

3. The solid-state imaging device according to claim 1, wherein
the insulating film
extends onto the light incident surface of the semiconductor layer.

4. The solid-state imaging device according to claim 1, wherein
the insulating film is
a silicon oxide film.

5. The solid-state imaging device according to claim 1, wherein
the insulating film is
a silicon nitride film.

6. The solid-state imaging device according to claim 1, wherein
the insulating film is
a metal oxide film having a positive fixed charge.

7. The solid-state imaging device according to claim 6, wherein
the metal oxide film contains
at least either yttrium oxide or lanthanum oxide.

8. The solid-state imaging device according to claim 1, wherein
the insulating film is
formed by atomic layer deposition (ALD).

9. The solid-state imaging device according to claim 1, wherein
the pixel separation unit contains
at least one element of hafnium, zirconium, aluminum, tantalum, titanium, yttrium, and lanthanoid elements.
